(19) United States
(12) Patent Application Publication
(10) Pub. No.: US 2019/0244943 A1
(43) Pub. Date: Aug. 8, 2019

(54) SEMICONDUCTOR PACKAGE AND MANUFACTURING METHOD THEREOF

(71) Applicant: Powertech Technology Inc., Hsinchu County (TW)

(72) Inventor: Wen-Jeng Fan, Hsinchu County (TW)

(73) Assignee: Powertech Technology Inc., Hsinchu County (TW)

(21) Appl. No.: 15/892,342

(22) Filed: Feb. 8, 2018

(51) Int. Cl. H01L 25/18; H01L 23/538; H01L 23/00

(52) U.S. Cl. CPC H01L 25/18; H01L 2224/1403; H01L 24/19; H01L 24/20; H01L 24/24; H01L 24/25; H01L 24/13; H01L 24/14; H01L 2224/2402; H01L 2224/24137; H01L 2224/24141; H01L 2224/73209; H01L 2224/25171; H01L 2224/13024; H01L 23/5389

(57) ABSTRACT

A semiconductor package including a redistribution layer, semiconductor devices, a semiconductor die, conductive features, an encapsulant and conductive terminals is provided. The semiconductor devices are disposed on the first surface of the redistribution layer. The semiconductor die, the conductive features, the encapsulant including openings are disposed on the second surface of the redistribution layer. The semiconductor die is embedded in the encapsulant, and the portion of the conductive features is protruded from the encapsulant. The conductive terminals including first elements disposed in the openings of the encapsulant and second elements disposed on the conductive features. A portion of the first elements and the second elements are protruded from the encapsulant, and a surface of each of the first elements opposite to the encapsulant and a surface of each of the second elements are aligned with a standoff baseline. A manufacturing method of semiconductor package is also provided.

### BACKGROUND OF THE INVENTION

### 1. Field of the Invention

The present invention generally relates to a package structure and a manufacturing method thereof, and more particularly, to a semiconductor package structure and a manufacturing method thereof.

### 2. Description of Related Art

In recently years, electronic apparatus are more important for human's life. In order for electronic apparatus design to achieve being light, slim, short, and small, semiconductor packaging technology has kept progressing, in attempt to develop products that are smaller in volume, lighter in weight, higher in integration, and more competitive in market. In addition, since the fusion of various functions is accelerated, multiple integrated circuit packages may be stacked upon one another to provide additional functionalities in a package-on-package (POP) structure. However, current POP assembly techniques are difficult to implement in small integrated circuit packages. As such, how to make integrated semiconductor packages keep their functionalities and thinner thickness thereof has become a challenge to researchers in the field.

### SUMMARY OF THE INVENTION

The disclosure provides a semiconductor package and a manufacturing method thereof, which reduces the size of the semiconductor package.

The disclosure provides a semiconductor package including a redistribution layer, a plurality of semiconductor devices, a semiconductor die, a plurality of conductive features, an encapsulant and a plurality of conductive terminals. The redistribution layer includes a first surface and a second surface opposite to the first surface. The semiconductor devices are disposed on the first surface of the redistribution layer and each of the semiconductor devices includes a surface. The semiconductor die is disposed on the second surface of the redistribution layer and includes an active surface. The surfaces of the semiconductor devices face towards the active surface of the semiconductor die. The redistribution layer is electrically connected to the semiconductor devices and the semiconductor die. The conductive features are disposed on the second surface of the redistribution layer and surround the semiconductor die. A portion of the conductive features is disposed above the semiconductor die opposite to the active surface. The encapsulant is disposed on the second surface of the redistribution layer and includes a plurality of openings. The semiconductor die is embedded in the encapsulant. The portion of the conductive features is protruded from the encapsulant. The conductive terminals includes a plurality of first elements disposed in the openings of the encapsulant and a plurality of second elements disposed on the portion of the conductive features opposite to the semiconductor die. A portion of the first elements and the second elements are protruded from the encapsulant. A surface of each of the first elements opposite to the encapsulant and a surface of each of the second elements are aligned with a standoff baseline.

The disclosure provides a semiconductor package including a redistribution layer, a semiconductor die, a plurality of conductive features, a plurality of conductive terminals and an encapsulant. The semiconductor die and a semiconductor device are disposed on two opposite surfaces of the redistribution layer. The redistribution layer is electrically connected to the semiconductor die and the semiconductor device. The conductive features are electrically connected to the redistribution layer and surround the semiconductor die opposite to the semiconductor device. The conductive terminals are electrically connected to the redistribution layer and include a plurality of first elements surrounding the conductive features and a plurality of second elements disposed on the conductive features and corresponding to the semiconductor die. The encapsulant encapsulates the semiconductor die and covers the first elements of the conductive terminals and the conductive features. A portion of the first elements of the conductive terminals is protruded from the encapsulant opposite to the redistribution layer and a portion of the conductive features are exposed by the encapsulant.

The disclosure provides a manufacturing method of a semiconductor package. The method includes at least the following steps. A redistribution layer is formed. The redistribution layer includes a first surface and a second surface. A semiconductor die is disposed on the second surface of the redistribution layer. The semiconductor die includes an active surface facing toward the second surface of the redistribution layer. A plurality of conductive features is formed on the second surface of the redistribution layer. A portion of the conductive features is formed above the semiconductor die. An encapsulant is formed on the second surface of the redistribution layer to encapsulate the semiconductor die. A plurality of semiconductor devices is disposed on the first surface of the redistribution layer. A plurality of conductive terminals is formed on the second surface of the redistribution layer. The conductive terminals include a plurality of first elements surrounding the conductive features and a plurality of second elements formed on the conductive features corresponding to the semiconductor die. A surface of each of the first elements opposite to the encapsulant and a surface of each of the second elements are aligned with a standoff baseline.

Based on the above, since the semiconductor devices and the semiconductor die are disposed in a face-to-face configuration, the overall thickness of the package structure may be reduced with simplified manufacturing processes. In addition, the redistribution layer is disposed between the semiconductor devices and the semiconductor die and electrically connected therebetween such that the semiconductor package may keep a short signal length in order to minimize a noise between operations and to improve performance.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are schematic cross-sectional views illustrating a manufacturing method of a semiconductor package according to an embodiment of the disclosure.

FIG. 2 is a schematic cross-sectional view illustrating a semiconductor package according to an embodiment of the disclosure.

FIG. 3 is a schematic cross-sectional view illustrating a semiconductor package according to an embodiment of the disclosure.

FIG. 4A and FIG. 4B are schematic cross-sectional views illustrating a manufacturing method of a semiconductor package according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

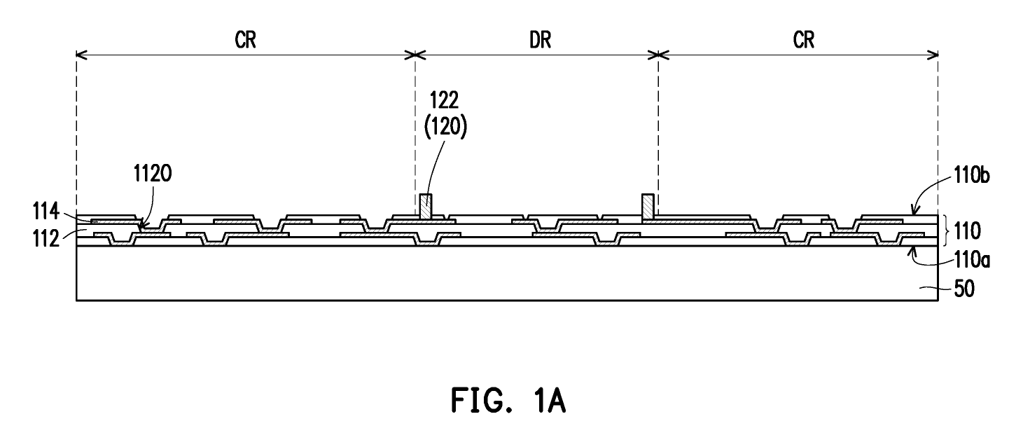

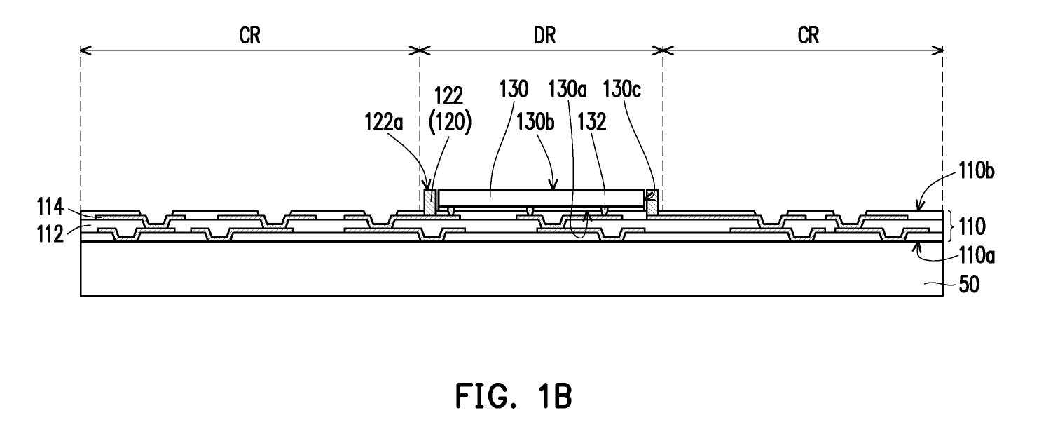

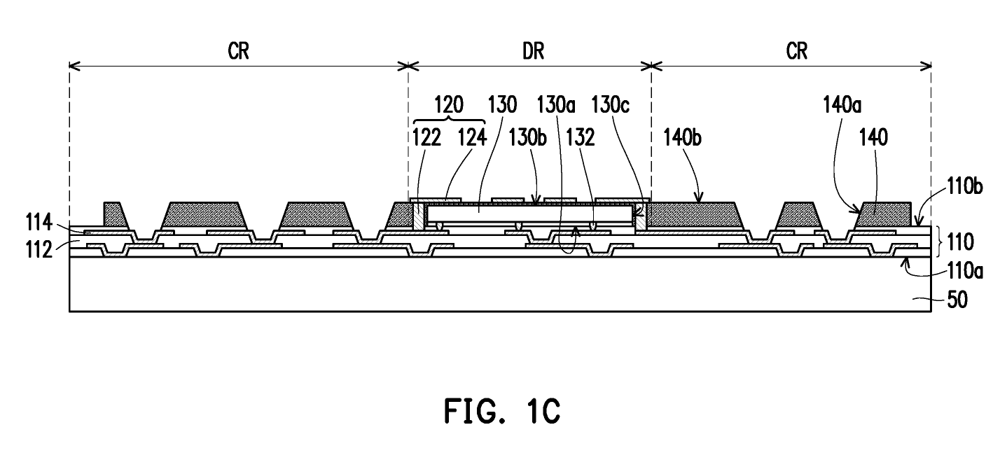

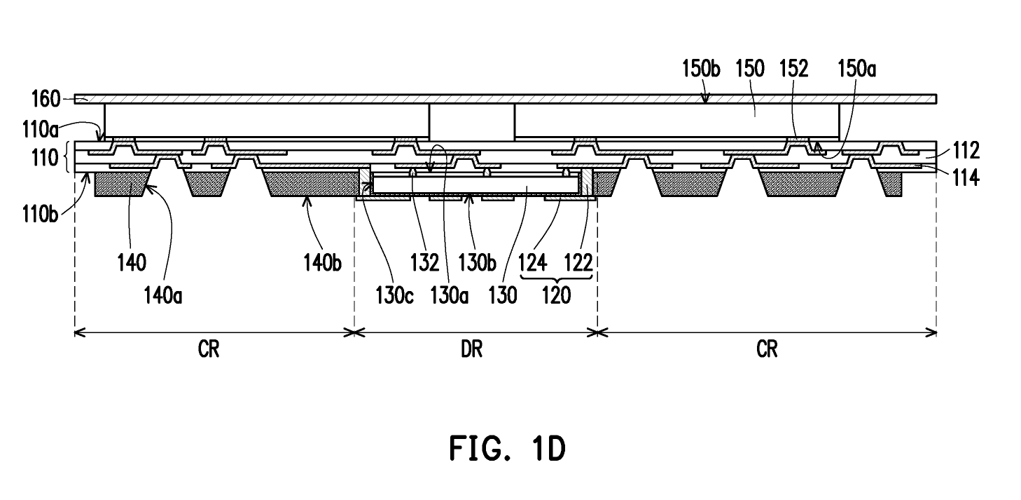

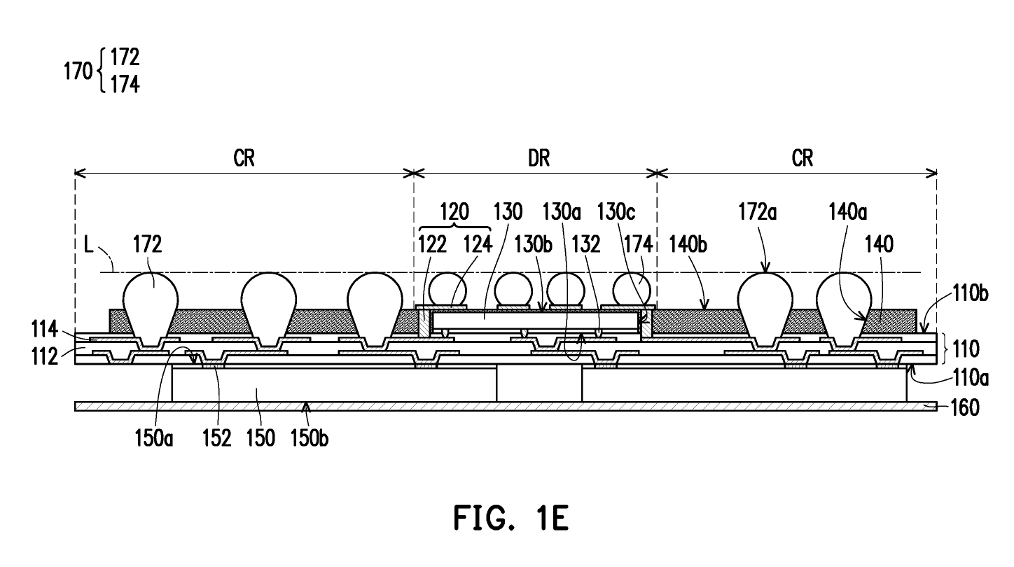

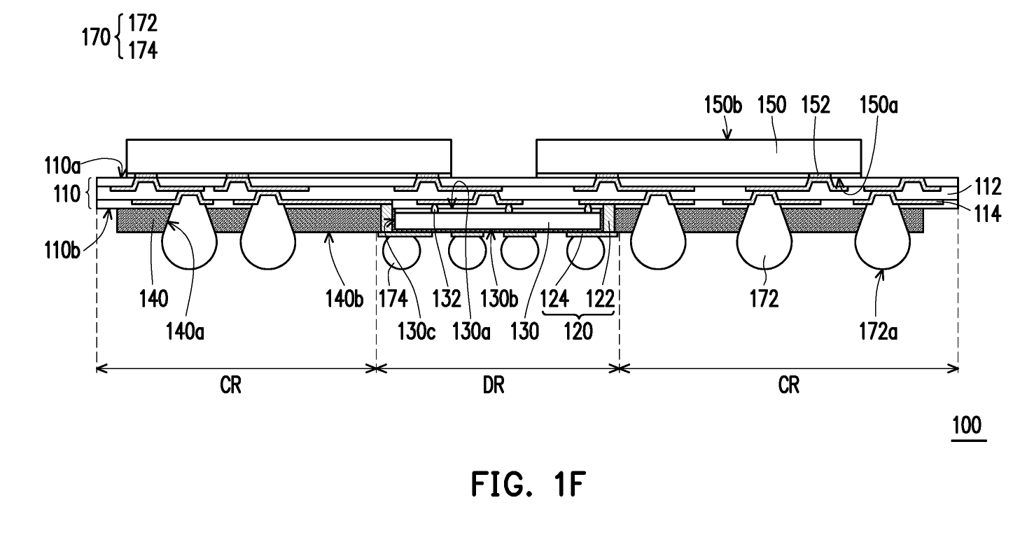

FIG. 1A to FIG. 1F are schematic cross-sectional views illustrating a manufacturing method of a semiconductor package according to an embodiment of the disclosure. Referring to FIG. 1A, a redistribution layer 110 is formed on a temporary carrier 50. The temporary carrier 50 may be a glass substrate or wafer substrate. In some embodiments, other suitable substrate material may be adapted as the temporary carrier 50 as long the material is able to withstand the subsequent processes while carrying the package structure formed thereon. The redistribution layer 110 may include a first surface 110a facing towards the temporary carrier 50 and a second surface 110b opposite to the first surface 110a. In some embodiments, the first surface 110a of the redistribution layer 110 may be in direct contact with the temporary carrier 50. In some other embodiments, a de-bonding layer (not illustrated) may be disposed between the first surface 110a of the redistribution layer 110 and the temporary carrier 50 to enhance the releasibility of the redistribution layer 110 from the temporary carrier 50 in the subsequent processes. For example, the de-bonding layer may be a LTHC (light to heat conversion) release layer or other suitable release layers, which is not limited thereto.

In some embodiments, the redistribution layer 110 may include at least one patterned dielectric layer 112 and at least one patterned conductive layer 114 stacked alternately. For example, a dielectric material may be formed over the temporary carrier 50 and a portion of the dielectric material is removed to form the patterned dielectric layer 112 including a plurality of openings 112O. The openings 112O of the patterned dielectric layer 112 may be formed using, for example, a photolithography (i.e., exposure and development processes) and an etching process. For instance, a material of the patterned dielectric layer 112 may include inorganic or organic dielectric materials such as silicon oxide, silicon nitride, polyimide, benezocyclobutene (BCB), or the like. The patterned conductive layer 114 may be formed over the patterned dielectric layer 112. In some embodiments, a seed layer (not illustrated) may be formed over the patterned dielectric layer 112. A patterned photoresist layer (not illustrated) having openings may be then formed on the patterned dielectric layer 112 using, for example, spin coating, baking, and photolithography processes. Next, a metal layer (not illustrated) may be deposited in the openings of the patterned photoresist layer using, for example, plating process or other suitable process. In some embodiments, metal layer (not illustrated) may be further deposited on the seed layers exposed by the openings of the patterned photoresist layer. Thereafter, the patterned photoresist layer may be stripped. In some embodiments, the seed layer formed underneath the photoresist layer may be removed using an etching process or other suitable removal process to form the patterned conductive layer 114.

In some embodiments, the abovementioned steps may be performed multiple times to obtain a multi-layered redistribution layer 110 as required by the circuit design. The topmost patterned dielectric layer 112 may have openings exposing at least the portion of the topmost patterned conductive layer 114. In some other embodiments, a plurality of conductive pads may be formed on the topmost of the patterned conductive layer 114 and the plurality of conductive pads may be referred as under-ball metallurgy (UBM) patterns for ball mount.

After forming the redistribution layer 110, a first portion 122 of conductive features 120 may be formed on the second surface 110b of the redistribution layer 110. In some embodiments, the redistribution layer 110 may include a die-disposing region DR and a contact region CR surrounding the die-disposing region DR. The first portion 122 of the conductive features 120 may be formed in the die-disposing region DR at the predetermined position. For example, the first portion 122 of the conductive features 120 may be formed by spin coating of a photoresist material layer, baking of the photoresist material layer, photolithography, plating (e.g., electro-plating or electro-less plating), and photoresist stripping processes. In some embodiments, the first portion 122 of the conductive features 120 may include conductive pillars (e.g. copper pillars, solder pillars, gold pillars, or the like), conductive bumps, conductive balls, or the combinations thereof.

Referring to FIG. 1B, a semiconductor die 130 is disposed on the second surface 110b of the redistribution layer 110 and is electrically connected to the redistribution layer 110. In some embodiments, the semiconductor die 130 may include integrated circuitry of a processor, such as Accelerated Processor Unit (APU), Central Processing Unit (CPU) or any type of semiconductor chip. For example, the semiconductor die 130 may include an active surface 130a facing towards the second surface 110b of the redistribution layer 110, a back surface 130b opposite to the active surface 130a and sidewalls 130c disposed between the active surface 130a and the back surface 130b. In some embodiments, the semiconductor die 130 may be disposed in the die-disposing region DR and the first portion 122 of the conductive features 120 may surround the semiconductor die 130 for further electrical connection. For example, the sidewall 130c of the semiconductor die 130 may be spaced apart from the first portion 122 of the conductive features 120.

In some embodiments, the height of the first portion 122 of the conductive features 120 may be greater than the thickness of the semiconductor die 130. In some other embodiments, the height of the first portion 122 may be equal to the thickness of the semiconductor die 130. In other words, a top surface 122a of the first portion 122 may be coplanar with the back surface 130b of the semiconductor die 130. In some embodiments, the semiconductor die 130 may include a plurality of conductive bumps 132 distributed at the active surface 130a. For example, the conductive bumps 132 of the semiconductor die 130 may be electrically connected to the patterned conductive layer 114 of the redistribution layer 110 though flip-chip bonding.

Referring to FIG. 1C, an encapsulant 140 including a plurality of openings 140a is formed on second surface 110 of the redistribution layer 110 to encapsulate the semiconductor die 130 and the first portion 122 of the conductive features 120. In other words, the semiconductor die 130 and the first portion 122 may be embedded in the encapsulant 140, and the first portion 122 may penetrate through the encapsulant 140. The encapsulant 140 may include a molding compound formed by a molding process (e.g., over-molding process). In some embodiments, the encapsulant 140 may be formed by an insulating material such as epoxy or other suitable resins, which is not limited thereto. In some other embodiments, a thickness of the encapsulant 140 may be greater than the height of the first portion 122 of the conductive features 120. In such case, the thickness of the encapsulant 140 may be reduced to expose the top surface 122a of the first portion 122 of the conductive features 120 for subsequent electrical connection. In some embodiments, after reducing the thickness of the encapsulant 140, a portion of the encapsulant 140 may cover the back surface 130b and the sidewall 130c of the semiconductor die 130.

In some alternative embodiments, a portion of the bulk semiconductor material of the semiconductor die 100 opposite to the active surface may be removed during the thickness reducing process. For example, after reducing the thickness of the encapsulant 140, the back surface 130b of the semiconductor die 130 and the top surface 122a of the first portion 122 of the conductive features 120 may be coplanar with the top surface 140b of the encapsulant 140. The thickness of the encapsulant 140 may be reduced by a grinding process, an etching process, or other suitable process.

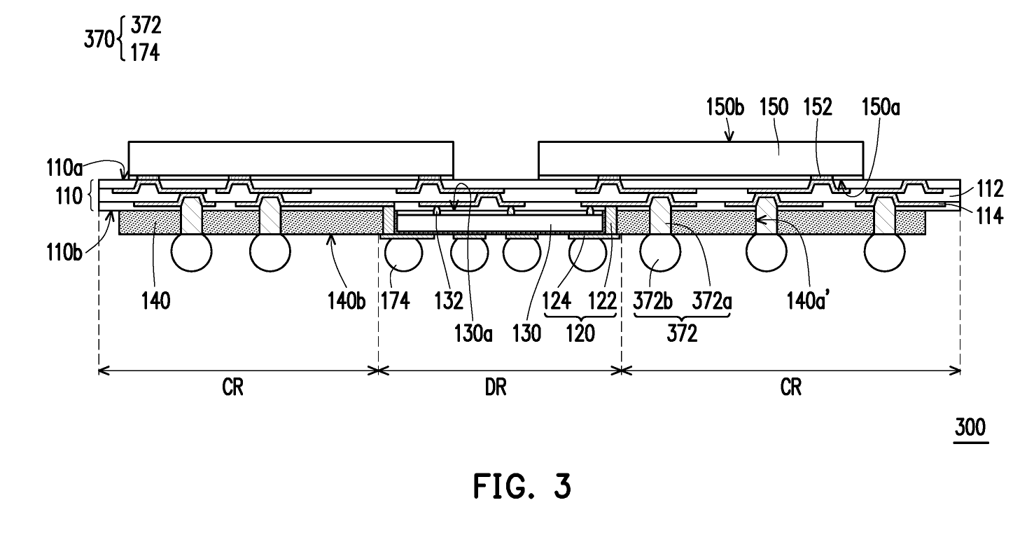

Subsequently, the openings 140a of the encapsulant 140 may be correspondingly formed on the peripheral region PR to expose at least a portion of the patterned conductive layer 114 of the redistribution layer 110. The openings 140a of the encapsulant 140 may be formed by, for example, a drilling process, an etching process, or other suitable process. In some embodiments, each of the openings 140a of the encapsulant 140 may be formed from the top surface 140b of the encapsulant 140 and extend towards the second surface 110b of the redistribution layer 110 and may have a tapered shape. In some other embodiments, the openings 140a of the encapsulant 140 may extend towards the second surface 110b of the redistribution layer 110 to have a uniform width and exemplary openings will be described in accompany with FIG. 3 in detail. The shape of the openings 140a of the encapsulant 140 may depend on the design requirement and construe no limitation in the disclosure.

In some embodiments, a second portion 124 of the conductive features 120 connected to the first portion 122 may be formed above the semiconductor die 130. For example, the second portion 124 may include conductive pads electrically coupled to the first portion 122. In some embodiments, the second portion 124 may be formed on the first portion 122 and extend towards the top surface 140b of the encapsulant 140 such that part of the second portion 124 may be formed above the semiconductor die 130 for further electrical connection. In some embodiments, part of the second portion 124 may be disposed on the top surface 140b of the encapsulant 140. The sequence of forming the openings 140a of the encapsulant 140 and the second portion 124 of the conductive features 120 construe no limitation in the disclosure.

After forming the openings 140a of the encapsulant 140 and the second portion 124 of the conductive features 120, the temporary carrier 50 may be removed to expose the first surface 110a of the redistribution layer 110. For example, the de-bonding layer between the redistribution layer 110 and the temporary carrier 50 may be peeled off using external energy such as UV laser, visible light, or heat applied to the de-bonding layer, or other suitable techniques. In some embodiments, without the de-bonding layer disposing between the temporary carrier 50 and the redistribution layer 110, removing the temporary carrier 50 from the redistribution layer 110 may be performed by physical treatment (e.g. UV irradiation process) or chemical treatment (e.g. chemical etching). Since the encapsulant 140 is rigid enough to serve as the support and withstand subsequent forming processes performed on the second surface 110b of the redistribution layer 110. In some embodiments, after removing the temporary carrier 50, the semi-product may be flipped upside down such that the second surface 110b faces upward for performing the subsequent processes.

Referring to FIG. 1D, a plurality of semiconductor devices 150 are disposed on the first surface 110a of the redistribution layer 110 opposite to the semiconductor die 130. The redistribution layer 110 is located between the semiconductor die 130 and the semiconductor devices 150. In some embodiments, the semiconductor devices 150 may include integrated circuitry of memory, such as Dynamic Random Access Memory (DRAM) or any chip required by system in package. Each of the semiconductor devices 150 may include an active surface 150a facing towards the first surface 110a of the redistribution layer 110. In some embodiments, each of the semiconductor devices 150 may include a plurality of conductive connectors 152 distributed at the active surface 150a. For example, the conductive connectors 152 of the semiconductor devices 150 may be electrically connected to the patterned conductive layer 114 of the redistribution layer 110. The active surfaces 150a of the semiconductor devices 150 and the active surface 130a of the semiconductor die 130 are disposed in a face-to-face configuration. In some embodiments, at least a portion of the semiconductor devices 150 and the semiconductor die 130 may overlap one another. In some embodiments, more than one of the semiconductor devices 150 are adjacent to each other and may overlap with the semiconductor die 130.

After disposing the semiconductor devices 150 on the redistribution layer 110, a protective layer 160 may be formed on to cover back surfaces 150b of the semiconductor devices 150 opposite to the active surfaces 150a. The protective layer 160 may be used to protect the semiconductor package from being damaged during the subsequent processes. For example, the protective layer 160 may be a dry film including polyimide, epoxy, benzocyclobutene resin, polymer or the like. After forming the protective layer 160, the semiconductor package may be flipped to have the top surface 140b of the encapsulant 140 face upward again for performing the subsequent processes.

Referring to FIG. 1E, a plurality of conductive terminals 170 are formed on the second surface 110b of the redistribution layer 110. In some embodiments, the conductive terminals 170 include a plurality of first elements 172 formed surrounding the conductive features 120 and a plurality of second elements 174 formed on the conductive features 120. For example, the conductive terminals 170 may be a ball grid array (BGA) formed by a ball placement process. In some embodiments, two stencils (not illustrated) with different sizes of holes are provided. For example, a first stencil may have larger holes than the holes of a second stencil.

For example, the first stencil having holes corresponding to the openings 140a of the encapsulant 140 is provided over the top surface 140b of the encapsulant 140. Subsequently, flux is printed on the openings 140a of the encapsulant 140 exposed by the holes of the first stencil. Thereafter, first conductive balls (e.g. solder balls, gold balls, copper balls, nickel balls, or the like) are placed over the first stencil. The first conductive balls are subjected to a specific vibration frequency such that the first conductive balls are dropped into the holes of the first stencil. Afterwards, a reflow process may be performed onto the first conductive balls so as to form the first elements 172 of the conductive terminals 170. For example, the connecting portion of the first elements 172 may be formed in the openings 140a and embedded in the encapsulant 140 to connect the patterned conductive layer 114, and the protruding portion on the connecting portion may be protruded from the top surface 140b of the encapsulant 140. The first elements 172 of the conductive terminals 170 are electrically connected to the patterned conductive layer 114 of the redistribution layer 110.

Similarly, the second stencil having holes corresponding to the second portion 124 of the conductive features 120 is provided. Subsequently, flux is printed on the second portion 124 of the conductive features 120 exposed by the holes of the second stencil. Thereafter, second conductive balls (e.g. the size may be smaller than the first conductive balls) are placed over the second stencil and then dropped into the holes of the second stencil though a specific vibration frequency. Afterwards, a reflow process may be performed to enhance the attachment between the second conductive balls and the second portion 124 of the conductive features 120 so as to form the second elements 174 of the conductive terminals 170. The second elements 174 of the conductive terminals 170 are electrically connected to the redistribution layer 110 through the conductive features 120. The forming sequence of the first elements 172 and the second elements 174 construe no limitation in the disclosure.

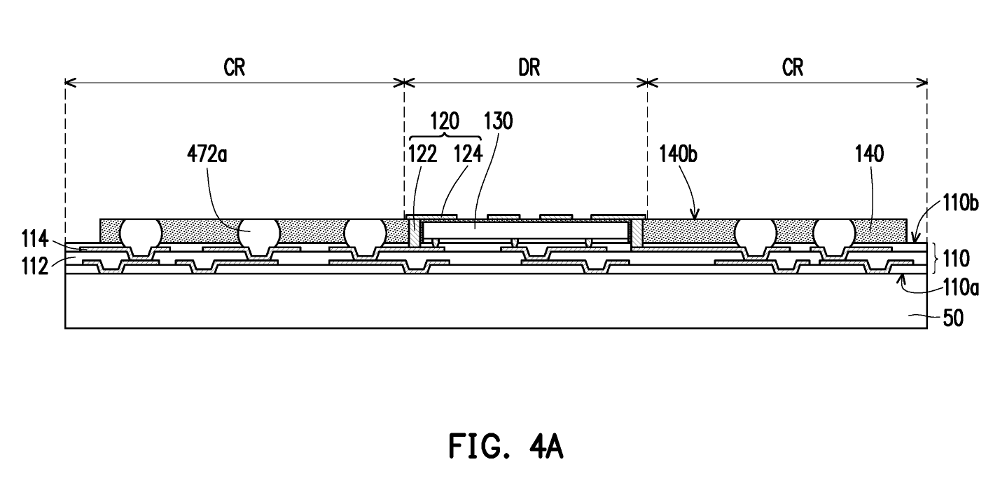

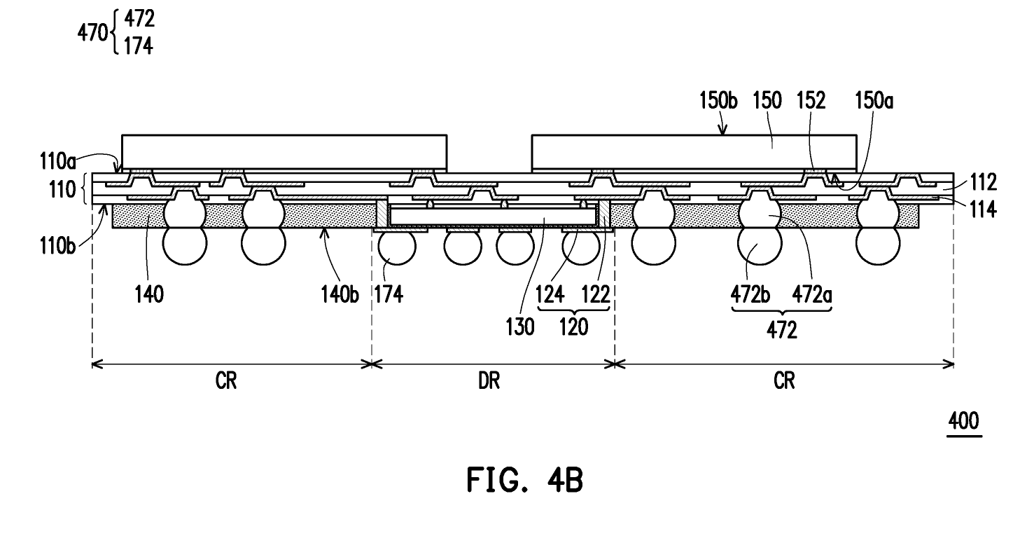

After forming the first elements 172 and the second elements 174, a surface 172a of each of the first elements 172 opposite to the encapsulant 140 and a surface 174a of each of the second elements 174 may be aligned with a standoff baseline L. Due to the second elements 174 formed corresponding to the die-disposing region DR, the number of conductive terminals 170 may be increased. In some embodiments, the first elements 172 and/or the second elements 174 may include a shape other than the spherical shape. Exemplary conductive terminals 170 will be described in accompany with FIG. 3 and FIG. 4 in detail.

Referring to FIG. 1F, after forming the conductive terminals 170, the protective layer 160 may be removed. Thereafter, the manufacturing process of a semiconductor package 100 may be completed. Since the semiconductor devices 150 and the semiconductor die 130 are disposed in a face-to-face configuration, the size of the semiconductor package 100 may be minimized. In addition, the redistribution layer 110 is disposed between the semiconductor devices 150 and the semiconductor die 130 and electrically connected therebetween such that the semiconductor package 100 may keep a short signal length in order to minimize a noise between operations and to improve performance. Moreover, since the redistribution layer 110 is formed as thin film, the encapsulant 140 may be formed to provide the rigidity to the overall structure and prevent the semiconductor package 100 from being damaged.

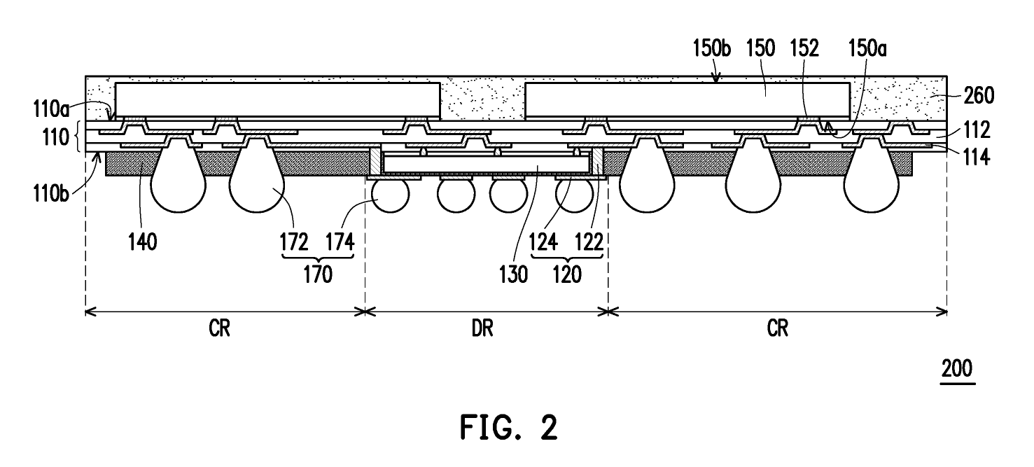

FIG. 2 is a schematic cross-sectional view illustrating a semiconductor package 200 according to an embodiment of the disclosure. The manufacturing method of the present embodiment is similar to the embodiment illustrated in FIG. 1A to FIG. 1F, where the step in FIG. 1D is optional. The difference lies in that the semiconductor devices 150 are embedded in an insulating layer 260.

For example, after disposing the semiconductor dies 150 on the redistribution layer 110, instead of forming the protective layer 160 as illustrated in FIG. 1D, the insulating layer 260 may be formed on the first surface 110a of the redistribution layer 110 to encapsulate the semiconductor devices 150 for protection. For example, the insulating layer 260 may cover the back surfaces 150b of the semiconductor devices 150. The insulating layer 260 may include a molding compound formed by a molding process. In some embodiments, a thinning process (e.g. a grinding process, an etching process or the like) may be performed to reduce the thickness of the insulating layer 260. The thinning process of the insulating layer 260 may be similar with the thickness reducing process of the encapsulant 140 and the detailed descriptions are omitted herein for brevity. In some embodiments, the insulating layer 260 may be formed after removing the protective layer 160 as illustrated in FIG. 1F depending on the design requirement. As such, the insulating layer 260 may provide protection for the semiconductor devices 150. In some other embodiments, after performing the thinning process, the back surface 150b of the semiconductor devices 150 may be exposed by the insulating layer 260 such that the overall thickness of the semiconductor package 200 may be reduced. Since the insulating layer 260 is formed to encapsulate the semiconductor devices 150, the rigidity of the semiconductor package 200 is increased.

FIG. 3 is a schematic cross-sectional view illustrating a semiconductor package 300 according to an embodiment of the disclosure. The manufacturing method of the present embodiment is similar to the embodiment illustrated in FIG. 1A to FIG. 1F. The main difference lies in that each of the first elements 372 of the conductive terminals 370 includes a via portion 372a and a protruding portion 372b connected to the via portion 372a. For example, the conductive terminals 170 as the embodiments described in FIG. 1E and FIG. 1F includes the first elements 172 and the second elements 174 using different sizes of conductive balls to form correspondingly in the openings 140a of the encapsulant 140 and on the second portion 124 of the conductive features 120. As compared to the conductive terminals 170 shown in FIG. 1E and FIG. 1F, the conductive terminals 370 shown in FIG. 3 include a plurality of the first elements 372 and a plurality of the second elements 174. Each of the first elements 372 may be formed by, for example, using plating the conductive pillar as the via portion 372a and mounting the conductive ball on the conductive pillar as the protruding portion 372b.

In the present embodiment, each of the openings 140a′ of the encapsulant 140 may be formed extending towards the redistribution layer 110 to have a uniform width using, for example, a drilling process, an etching process or other suitable process. After forming the openings 140a′ of the encapsulant 140, the via portion 372a may be formed in the openings 140a′. In some embodiments, the encapsulant 140 may expose at least a portion of the via portion 372a for the protruding portion 372b to be formed thereon. For example, after forming the protective layer 160 as illustrated in FIG. 1D, the semi-product may be flipped upside down and the top surface 140b of the encapsulant 140 faces upward for forming the protruding portion 372b and the second elements 174. In some embodiments, the protruding portion 372b of the first elements 372 and the second elements 174 may be formed during the same process (e.g. a ball placement process, a plating process or other suitable process). For example, the protruding portion 372b may include conductive balls, conductive bumps, conductive pillars or the combinations thereof. As such, after forming the conductive terminals 370, top surfaces of the protruding portion 372b and top surfaces of the second elements 174 may be aligned with the standoff baseline.

In some alternative embodiments, the first portion 122 of the conductive features 120 may be formed in the same process with the via portion 372a of the first elements 372 using, for example, a plating process. For instance, during the process of forming the openings 140a′, the through holes for forming the first portion 122 of the conductive features 120 may be formed in the same process at the predetermined positions in the encapsulant 140. Subsequently, after forming the first portion 122, the second portion 124 of the conductive features 120 may be formed as the ball pads before forming the protruding portion 372b of the first elements 372.

FIG. 4A and FIG. 4B are schematic cross-sectional views illustrating a manufacturing method of a semiconductor package according to an embodiment of the disclosure. The present embodiment is similar to the embodiment illustrated in FIG. 1A to FIG. 1F and the difference therebetween is the first elements 472 of the conductive terminals 470.

Referring to FIG. 4A and FIG. 4B, the first elements 472 including a connecting portion 472a formed on the second surface 110b of the redistribution layer 110 and a protruding portion 472b connected to the connecting portion 472a. In some embodiments, the connecting portion 472 may be formed by, for example, a ball placement process before forming the encapsulant 140. For instance, after forming the redistribution layer 110 and/or the first portion 122 of the conductive features 120 and/or after disposing the semiconductor die 130, the first stencil having holes corresponding to the patterned conductive layer 114 exposed by the patterned dielectric layer 112 may be provided. Subsequently, a layer of flux is printed on the patterned conductive layer 114 of the redistribution layer 110 exposed by the holes of the first stencil. Thereafter, first conductive balls are placed over the first stencil and then dropped into the holes of the first stencil though a specific vibration frequency. Afterwards, a reflow process may be performed onto the first conductive balls.

After performing the ball placement process, forming the first portion 122 of the conductive features 120 and disposing the semiconductor die 130, the encapsulant 140 is subsequently formed on the second surface 110b of the redistribution layer 110. In some embodiments, a thinning process (e.g. a grinding process, an etching process, a milling process, a polishing process) may be performed to reduce the thickness of the encapsulant 140 and to form the connecting portion 472a of the first elements 472. For example, after performing the thinning process, a top surface 472a′ of the connecting portion 472a opposite to the second surface 110b of the redistribution layer 110 and the top surface 122a of the first portion 122 of the conductive features 120 may be exposed by the encapsulant 140. In some embodiments, the top surface 472a′ of the connecting portion 472a and the top surface 122a of the first portion 122 of the conductive features 120 may be coplanar with the top surface 140b of the encapsulant 140 as shown in FIG. 4A.

Subsequently, after disposing the semiconductor devices 150 as illustrated in FIG. 1D, the protruding portion 472b and the second elements 474 may be correspondingly formed on the connecting portion 472a and the second portion 124 of the conductive features 120. The forming process of the protruding portion 472b and the second elements 474 may be similar with the process described in FIG. 3 and the detailed descriptions are omitted herein. In some embodiments, the connecting portion 472a and the protruding portion 472b may be connected to each other using, for example, a thermal compression process and/or a reflow process such that the connecting portion 472a and the protruding portion 472b may be formed into a one-body structure for enhancement the structure of the first elements 472.

Based on the above, since the semiconductor devices and the semiconductor die are disposed in a face-to-face configuration, the overall thickness of the package structure may be reduced with simplified manufacturing processes. In addition, the redistribution layer is disposed between the semiconductor devices and the semiconductor die and electrically connected therebetween such that the semiconductor package may keep a short signal length in order to minimize a noise between operations and to improve performance. Moreover, since the redistribution layer is formed as thin film, the encapsulant may be formed to provide the rigidity of the overall structure so as to prevent the semiconductor package from being damaged. Furthermore, since the conductive features electrically connected to the redistribution layer and the second portion is formed corresponding to the semiconductor die, the second elements of the conductive terminals may be formed corresponding to the die-disposing region and the first elements of the conductive terminals may be formed corresponding to the contact region. As a result, the semiconductor package with the increased I/O density may be provided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor package, comprising:
a redistribution layer comprising a first surface and a second surface opposite to the first surface;
a plurality of semiconductor devices disposed on the first surface of the redistribution layer and each of the semiconductor devices comprising a surface;
a semiconductor die disposed on the second surface of the redistribution layer and comprising an active surface, wherein the surfaces of the semiconductor devices face towards the active surface of the semiconductor die, the redistribution layer is electrically connected to the semiconductor devices and the semiconductor die;
a plurality of conductive features disposed on the second surface of the redistribution layer and surrounding the semiconductor die, a portion of the conductive features is disposed above the semiconductor die opposite to the active surface;
an encapsulant disposed on the second surface of the redistribution layer and comprising a plurality of openings, wherein the semiconductor die is embedded in the encapsulant, and the portion of the conductive features is protruded from the encapsulant; and
a plurality of conductive terminals comprising a plurality of first elements disposed in the openings of the encapsulant and a plurality of second elements disposed on the portion of the conductive features opposite to the semiconductor die, wherein a portion of the first elements and a portion of the second elements are protruded from the encapsulant, and a surface of each of the first elements opposite to the encapsulant and a surface of each of the second elements are aligned with a standoff baseline.

2. The semiconductor package according to claim 1, further comprising:
an insulating layer disposed on the first surface of the redistribution layer, wherein the semiconductor devices are embedded in the insulating layer.

3. The semiconductor package according to claim 1, wherein each of the conductive features comprises a first portion disposed on the second surface of the redistribution layer and penetrating though the encapsulant and a second portion connected to the first portion and extending towards the semiconductor die.

4. The semiconductor package according to claim 1, wherein the size of each of the first elements of the conductive terminals is greater than the size of each of the second elements of the conductive terminals.

5. A semiconductor package, comprising:
a redistribution layer;
a semiconductor die and a semiconductor device disposed on two opposite surfaces of the redistribution layer, wherein the redistribution layer is electrically connected to the semiconductor die and the semiconductor device;
a plurality of conductive features electrically connected to the redistribution layer and surrounding the semiconductor die opposite to the semiconductor device;
a plurality of conductive terminals electrically connected to the redistribution layer and comprising a plurality of first elements surrounding the conductive features and a plurality of second elements disposed on the conductive features and corresponding to the semiconductor die; and
an encapsulant encapsulating the semiconductor die and covering the first elements of the conductive terminals and the conductive features, wherein a portion of the first elements of the conductive terminals is protruded from the encapsulant opposite to the redistribution layer and a portion of the conductive features are exposed by the encapsulant.

6. The semiconductor package according to claim 5, wherein the semiconductor devices comprises a plurality of conductive connectors facing a first surface of the redistribution layer and the semiconductor die comprises a plurality of conductive bumps facing a second surface of the redistribution layer opposite to the first surface.

7. The semiconductor package according to claim 5, further comprising:
an insulating layer disposed on the redistribution layer, wherein the semiconductor device is embedded in the insulating layer.

8. The semiconductor package according to claim 5, wherein a surface of each of the first elements opposite to the encapsulant and a surface of each of the second elements are aligned with a standoff baseline.

9. The semiconductor package according to claim 5, wherein each of the first elements of the conductive terminals comprises a via portion and a protruding portion connected to the via portion, the via portion has a uniform width and is embedded in the encapsulant, and the protruding portion is protruded from the encapsulant.

10. The semiconductor package according to claim 5, wherein each of the first elements of the conductive terminals comprises a connecting portion and a protruding portion connected to the connecting portion, the connecting portion has a curved sidewall and is embedded in the encapsulant, and the protruding portion is protruded from the encapsulant.

11. A manufacturing method of a package structure, comprising:
forming a redistribution layer, wherein the redistribution layer comprises a first surface and a second surface;
disposing a semiconductor die on the second surface of the redistribution layer, wherein the semiconductor die comprises an active surface facing toward the second surface of the redistribution layer;
forming a plurality of conductive features on the second surface of the redistribution layer, wherein a portion of the conductive features is formed above the semiconductor die;
forming an encapsulant on the second surface of the redistribution layer to encapsulate the semiconductor die;
disposing a plurality of semiconductor devices on the first surface of the redistribution layer; and
forming a plurality of conductive terminals on the second surface of the redistribution layer, wherein the conductive terminals comprises a plurality of first elements surrounding the conductive features and a plurality of second elements formed on the conductive features corresponding to the semiconductor die, and a surface of each of the first elements opposite to the encapsulant and a surface of each of the second elements are aligned with a standoff baseline.

12. The manufacturing method according to claim 11, further comprising:
forming an insulating layer on the first surface of the redistribution layer to encapsulate the semiconductor devices after forming the encapsulant on the second surface of the redistribution layer.

13. The manufacturing method according to claim 11, wherein forming the conductive features comprises:
forming the first portion on the second redistribution layer; and
after forming the encapsulant, forming the second portion on the first portion, wherein the second portion is exposed by the encapsulant and corresponds to the semiconductor die.

14. The manufacturing method according to claim 11, wherein the conductive terminals are formed by a ball placement process and the size of the first elements are greater than the size of the second elements.

15. The manufacturing method according to claim 11, wherein forming the encapsulant comprises:
forming an insulating material on the second surface of the redistribution layer to encapsulate the semiconductor die; and
forming a plurality of openings surrounding the conductive features on the insulating material to form the encapsulant.

16. The manufacturing method according to claim 15, wherein forming the first elements of the conductive terminals comprises:
forming a via portion in the openings of the encapsulant, wherein the via portion has a uniform width; and
forming a protruding portion on the via portion.

17. The manufacturing method according to claim 16, wherein after forming the via portion of the first elements, the protruding portion of the first elements is formed with the second elements of the conductive terminals during the same process.

18. The manufacturing method according to claim 15, wherein forming the first elements of the conductive terminals comprises:
forming a connecting portion before forming the encapsulant, wherein the connecting portion has a curved sidewall; and
forming a protruding portion on the connecting portion after forming the encapsulant.

19. The manufacturing method according to claim 18, wherein after forming the connecting portion of the first elements, the protruding portion of the first elements is formed with the second elements of the conductive terminals during the same process.

20. The manufacturing method according to claim 11, further comprising:
forming a protective layer on the semiconductor devices opposite to the redistribution layer after disposing the semiconductor devices; and
removing the protective layer after forming the conductive terminals.
